(19) United States
(12) Patent Application Publication
(10) Pub. No.: US 2014/0042638 A1
(43) Pub. Date: Feb. 13, 2014

(54) SEMICONDUCTOR PACKAGE AND METHOD OF FABRICATING THE SAME

(71) Applicant: SILICONWARE PRECISION INDUSTRIES CO., L, Taichung (TW)

(72) Inventors: Hung-Wen Liu, Taichung (TW); Hsi-Chang Hsu, Taichung (TW); Hsin-Hung Chou, Taichung (TW); Hsin-Yi Liao, Taichung (TW); Chiang-Cheng Chang, Taichung (TW)

(73) Assignee: SILICONWARE PRECISION INDUSTRIES CO., LTD., Taichung (TW)

(21) Appl. No.: 13/663,742

(22) Filed: Oct. 30, 2012

(30) Foreign Application Priority Data
Aug. 13, 2012 (TW) 101129157

(51) Int. Cl. H01L 23/48; H01L 21/60

(52) U.S. Cl. 257/774; 438/118; 257/E23.011; 257/E21.506

(57) ABSTRACT

A semiconductor package is provided, which includes: a soft layer having opposite first and second surfaces and first conductive through hole vias; a chip embedded in the soft layer and having an active surface exposed from the first surface of the soft layer; a support layer formed on the second surface of the soft layer and having second conductive through hole vias in electrical connection with the first conductive through hole vias; a first RDL structure formed on the first surface of the soft layer and electrically connected to the active surface of the chip; and a second RDL structure formed on the support layer and electrically connected to the first RDL structure through the first and second conductive through hole vias. The invention prevents package warpage by providing the support layer, and allows disposing of other packages or electronic elements by electrically connecting the RDL structures through the conductive through hole vias.

### BACKGROUND OF THE INVENTION

1. Field of the Invention

The present invention relates to semiconductor packages and methods of fabricating the same, and, more particularly, to a wafer level semiconductor package and a method of fabricating the same.

2. Description of Related Art

Along with the development of semiconductor technologies, various package types have been developed for semiconductor products. A chip scale package (CSP) is characterized in that the package size is equal to or slightly greater than a chip disposed in the package.

In a conventional CSP structure as disclosed by U.S. Pat. Nos. 5,892,179, 6,103,552, 6,287,893, 6,350,668 and 6,433,427, a build-up structure is directly disposed on a chip and a redistribution layer (RDL) technique is used to re-route electrode pads of the chip.

However, the application of the RDL technique or formation of conductive traces on the chip is limited by the size of the chip or the area of the active surface of the chip. Particularly, along with increased integration and continuous reduction in size, chips lack sufficient surface area for accommodating more solder balls for electrical connection to an external device.

Accordingly, U.S. Pat. No. 6,271,469 discloses a method of fabricating a wafer level chip scale package (WLCSP), which involves forming a build-up layer on a chip so as to provide sufficient surface area for mounting I/O terminals or solder balls.

Referring to FIG. 1A, a chip 102 having an active surface 106 with a plurality of electrode pads 108 and a non-active surface 114 opposite to the active surface 106 is provided and attached to an adhesive film 104 through the active surface 106 thereof. Then, an encapsulant 112 made of an epoxy resin, for example, is formed to encapsulate the non-active surface 114 and side surfaces 116 of the chip 102. Subsequently, the adhesive film 104 is removed by heating to thereby expose the active surface 106 and the electrode pads 108 of the chip 102. Further, referring to FIG. 1B, by using an RDL technique, an RDL structure 14 is formed on the active surface 106 of the chip 102 and the surface of the encapsulant 112. Then, a solder mask layer 136 with a plurality of openings is formed on the RDL structure 14, and a plurality of solder balls 138 are disposed in the openings of the solder mask layer 136.

In the package, the surface of the encapsulant 112 is greater than the active surface 106 of the chip 102 and therefore allows more solder balls 138 to be disposed thereon for electrically connection to an external device.

However, since the chip 102 is only supported by the adhesive film 104, warpage can easily occur to the adhesive film 104 and the encapsulant 112. Further, a positional deviation can easily occur to the chip 102 due to softening or expansion of the adhesive film 104 caused by heat, especially during a molding process, thereby adversely affecting the electrical connection between the RDL structure and the electrode pads 108 of the chip 102. Furthermore, no conductive through hole via is formed in the package and therefore the upper and lower RDL structures cannot be electrically connected to each other. As such, other packages or electronic elements cannot be disposed on the package.

Therefore, there is a need to provide a semiconductor package and a fabrication method thereof so as to overcome the drawbacks.

### SUMMARY OF THE INVENTION

In view of the drawbacks, the present invention provides a method of fabricating a semiconductor package, which comprises: providing a carrier having an adhesive layer formed on a surface thereof; providing at least a chip having an active surface with a plurality of electrode pads and a non-active surface opposite to the active surface, and disposing the chip on the adhesive layer through the active surface thereof; forming a soft layer on the adhesive layer for encapsulating the chip, wherein the soft layer has a first surface in contact with the adhesive layer and a second surface opposite to the first surface; forming a support layer on the second surface of the soft layer so as to sandwich the soft layer between the support layer and the adhesive layer, wherein the support layer has a third surface opposite to the second surface of the soft layer; removing the carrier and the adhesive layer so as to expose the active surface of the chip from the first surface of the soft layer; forming a plurality of first conductive through hole vias in the soft layer; forming a first redistribution layer (RDL) structure on the active surface of the chip and the first surface of the soft layer such that the first RDL structure is electrically connected to the first conductive through hole vias; forming in the support layer a plurality of second conductive through hole vias in electrical connection with the first conductive through hole vias; and forming a second RDL structure on the third surface of the support layer such that the second RDL structure is electrically connected to the first RDL structure through the first and second conductive through hole vias.

In the method, forming the first RDL structure can further comprise: forming a first dielectric layer on the active surface of the chip and the first surface of the soft layer; forming a first circuit layer on the first dielectric layer, and forming a plurality of first conductive vias in the first dielectric layer for electrically connecting the first circuit layer to the electrode pads of the chip and the first conductive through hole vias; and forming a first insulating layer on the first dielectric layer and the first circuit layer, and exposing a portion of the first circuit layer from the first insulating layer.

In the method, forming the second RDL structure can further comprise the steps of: forming a second dielectric layer on the third surface of the support layer; forming a second circuit layer on the second dielectric layer and forming a plurality of second conductive vias in the second dielectric layer for electrically connecting the second circuit layer and the second conductive through hole vias; and forming a second insulating layer on the second dielectric layer and the second circuit layer and exposing a portion of the second circuit layer from the second insulating layer.

In the method, forming the first conductive through hole vias can further comprise: forming a plurality of first through holes in the soft layer; and forming the first conductive through hole vias in the first through holes.

In the method, forming the second conductive through hole vias can further comprise: forming a plurality of second through holes in the support layer; and forming the second conductive through hole vias in the second through holes.

The present invention further provides a semiconductor package, which comprises: a soft layer having opposite first and second surfaces and a plurality of first conductive through hole vias; at least a chip embedded in the soft layer, wherein the chip has an active surface with a plurality of electrode pads and a non-active surface opposite to the active surface, and the active surface of the chip is exposed from the first surface of the soft layer; a support layer formed on the second surface of the soft layer and having a third surface opposite to the second surface of the soft layer, wherein a plurality of second conductive through hole vias are formed in the support layer and in electrical connection with the first conductive through hole vias; a first RDL structure formed on the active surface of the chip and the first surface of the soft layer and electrically connected to the electrode pads of the chip and the first conductive through hole vias of the soft layer; and a second RDL structure formed on the third surface of the support layer and electrically connected to the first RDL structure through the first and second conductive through hole vias.

In an embodiment, the support layer is made of silicon, and the second conductive through hole vias are through silicon vias (TSV). In another embodiment, the support layer is made of glass, and the second conductive through hole vias are through glass vias (TGV). The soft layer can be made of ajinomoto build-up film (ABF), polyimide or silicone.

Therefore, the present invention provides a support layer made of silicon or glass for supporting the soft layer so as to prevent warpage of the package. Further, by electrically connecting the first and second RDL structures through the first and second conductive through hole vias, the present invention allows disposing of other packages or electronic elements.

### BRIEF DESCRIPTION OF DRAWINGS

FIGS. 1A and 1B are cross-sectional views showing a conventional WLCSP package;

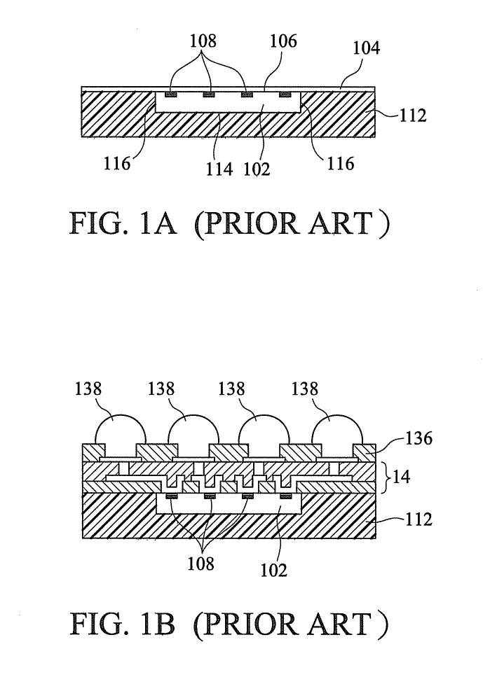

FIGS. 2A to 2J are cross-sectional views showing a method of fabricating a semiconductor package according to the present invention;

FIG. 3 is a cross-sectional view showing an application of the semiconductor package according to the present invention; and

FIG. 4 is a cross-sectional view showing another application of the semiconductor package according to the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms, such as “first”, “second”, “on” etc., are merely for illustrative purpose and should not be construed to limit the scope of the present invention.

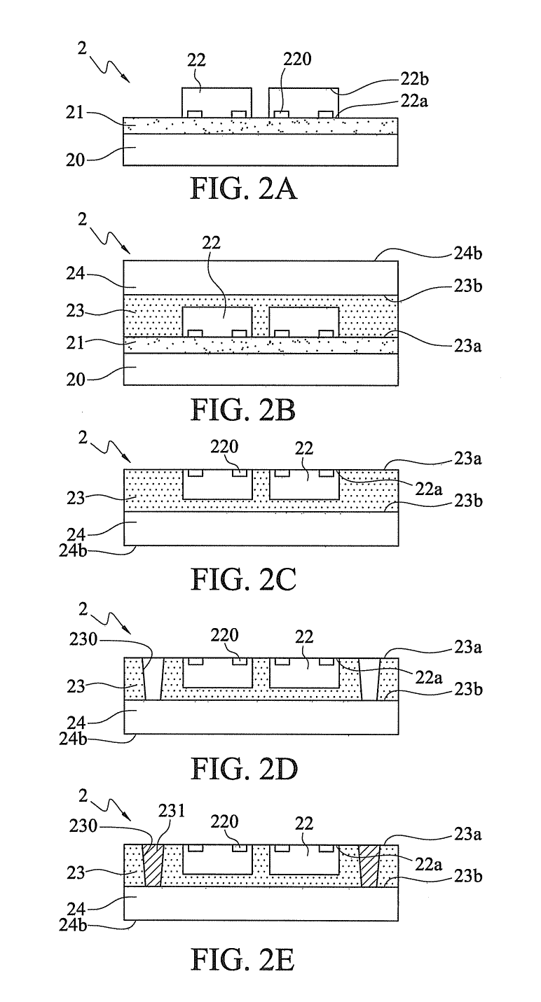

FIGS. 2A to 2J are cross-sectional views showing a method of fabricating a semiconductor package according to an embodiment of the present invention.

Referring to FIG. 2A, a carrier 20 is provided with an adhesive layer 21 formed thereon. At least a chip 22 having an active surface 22a with a plurality of electrode pads 220 and a non-active surface 22b opposite to the active surface 22a is provided and disposed on the adhesive layer 21 through the active surface 22a thereof.

Referring to FIG. 2B, a soft layer 23 is formed on the adhesive layer 21 so as to encapsulate the chip 22. The soft layer 23 has a first surface 23a in contact with the adhesive layer 21, and a second surface 23b opposite to the first surface 23a. The soft layer 23 can be made of, but not limited to, ajinomoto build-up film (ABF), polyimide or polymerized siloxanes (also called silicone or polysiloxanes). Subsequently, a support layer 24 is formed on the second surface 23b of the soft layer 23 so as to sandwich the soft layer 23 between the support layer 24 and the adhesive layer 21. The support layer 24 can be made of glass or silicon. The support layer 24 has a third surface 24b opposite to the second surface 23b of the soft layer 23.

Referring to FIG. 2C, the carrier 20 and the adhesive layer 21 are removed to expose the active surface 22a of the chip 22 from the first surface 23a of the soft layer 23.

Referring to FIG. 2D, a plurality of first through holes 230 are formed in the soft layer 23.

Referring to FIG. 2E, by performing an electroplating process, a plurality of first conductive through hole vias 231 are formed in the first through holes.

Referring to FIG. 2F, a first RDL structure 25 is formed on the active surface 22a of the chip 22 and the first surface 23a of the soft layer 23 and electrically connected to the first conductive through hole vias 231. In particular, forming the first RDL structure 25 includes: forming a first dielectric layer 251 made of, for example, a low temperature passivation material on the active surface 22a of the chip 22 and the first surface 23a of the soft layer 23; forming a first circuit layer 252 on the first dielectric layer 251, and forming a plurality of first conductive vias 253 in the first dielectric layer 251 for electrically connecting the first circuit layer 252 to the electrode pads 220 and the first conductive through hole vias 231; and forming a first insulating layer 254 on the first dielectric layer 251 and the first circuit layer 252, and exposing a portion of the first circuit layer 252 through a plurality of first openings 250 of the first insulating layer 254.

Referring to FIG. 20, the support layer 24 is thinned to have a third surface 24b′ opposite to the second surface 23b. In another embodiment, the thinning process can be omitted and the subsequent processes are directly performed to the third surface 24b of the support layer 24.

Referring to FIG. 2H, a plurality of second conductive through hole vias 241 are formed in the support layer 24 and in electrical connection with the first conductive through hole vias 231. In an embodiment, the support layer 24 is made of silicon, and the second conductive through hole vias 241 are through silicon vias (TSV). In another embodiment, the support layer 24 is made of glass, and the second conductive through hole vias 241 are through glass vias (TGV).

Referring to FIG. 2I, a second RDL structure 26 is formed on the third surface 24b′ of the support layer 24 and electrically connected to the first RDL structure 25 through the first conductive through hole vias 231 and the second conductive through hole vias 241. In an embodiment, forming the second RDL structure 26 includes: forming a second dielectric layer 261 made of, for example, a low temperature passivation material on the third surface 24b′ of the support layer 24; forming a second circuit layer 262 on the second dielectric layer 261, and forming a plurality of second conductive vias 263 in the second dielectric layer 261 for electrically connecting the second circuit layer 262 and the second conductive through hole vias 241; and forming a second insulating layer 264 on the second dielectric layer 261 and the second circuit layer 262, and exposing a portion of the second circuit layer 262 through a plurality of second openings 260 of the second insulating layer 264.

Referring to FIG. 2J, a plurality of conductive elements 27 are disposed on the a portion of the first circuit layer 252 exposed from the first openings 250 so as to be electrically connected to the electrode pads 220 of the chip 22 through the first circuit layer 252.

According to the method, the present invention further provides a semiconductor package, which has: a soft layer 23 having opposite first and second surfaces 23a, 23b and a plurality of first conductive through hole vias 231; at least a chip 22 embedded in the soft layer 23, wherein the chip 22 has an active surface 22a with a plurality of electrode pads 220 and a non-active surface 22b opposite to the active surface 22a, and the active surface 22a of the chip 22 is exposed from the first surface 23a of the soft layer 23; a support layer 24 formed on the second surface 23b of the soft layer 23 and having a third surface 24b′ (or a third surface 24b if the support layer 24 is not thinned) opposite to the second surface 23b of the soft layer 23, wherein a plurality of second conductive through hole vias 241 are formed in the support layer 24 and in electrical connection with the first conductive through hole vias 231; a first RDL structure 25 formed on the active surface 22a of the chip 22 and the first surface 23a of the soft layer 23 and electrically connected to the electrode pads 220 of the chip 22 and the first conductive through hole vias 231 of the soft layer 23; and a second RDL structure 26 formed on the third surface 24b′ of the support layer 24 and electrically connected to the first RDL structure 25 through the first conductive through hole vias 231 and the second conductive through hole vias 241.

The first RDL structure 25 has a first dielectric layer 251 formed on the active surface 22a of the chip 22 and the first surface 23a of the soft layer 23, a first circuit layer 252 formed on the first dielectric layer 251, a plurality of first conductive vias 253 formed in the first dielectric layer 251 for electrically connecting the first circuit layer 252 to the electrode pads 220 and the first conductive through hole vias 231, and a first insulating layer 254 formed on the first dielectric layer 251 and the first circuit layer 252 and exposing portion of the first circuit layer 252.

The second RDL structure 26 has a second dielectric layer 261 formed on the third surface 24b′ of the support layer 24, a second circuit layer 262 formed on the second dielectric layer 261, a plurality of second conductive vias 263 formed in the second dielectric layer 261 for electrically connecting the second circuit layer 262 and the second conductive through hole vias 241, and a second insulating layer 264 formed on the second dielectric layer 261 and the second circuit layer 262 and exposing a portion of the second circuit layer 262.

The support layer 24 can be made of silicon or glass. The support layer 24 enhances the strength of the package so as to avoid warpage of the package. If the support layer 24 is made of glass, its high transparency facilitates alignment of the second RDL structure. The soft layer 23 can be made of ABF, polyimide or silicone.

The package of the present invention allows other packages or electronic elements to be disposed thereon, thereby forming a stack package structure.

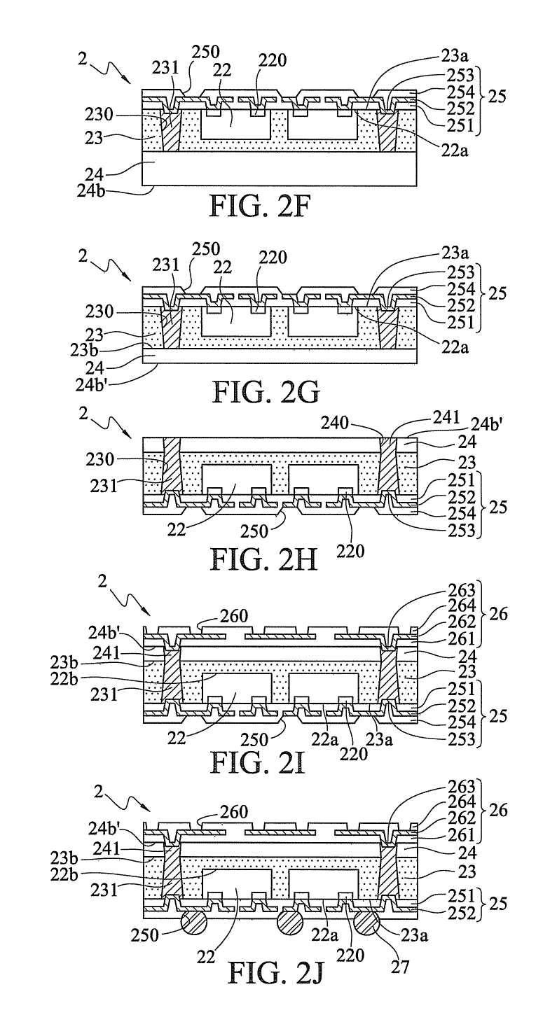

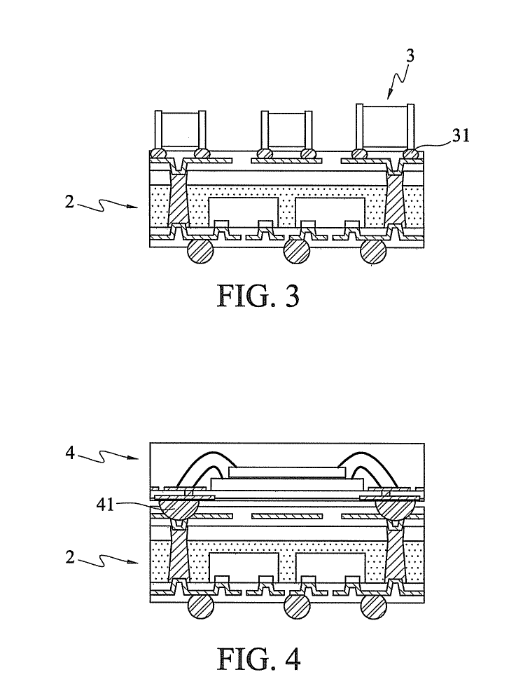

FIGS. 3 and 4 are cross-sectional views showing applications of the semiconductor package of the present invention.

Referring to FIG. 3, a plurality of electronic elements 3 are disposed on the semiconductor package 2 through a plurality of conductive elements 31.

Referring to FIG. 4, another package 4 is disposed on the semiconductor package 2 through a plurality of conductive elements 41.

Therefore, the present invention provides a support layer made of silicon or glass between the RDL structure and the soft layer so as to enhance the strength of the package, thereby preventing warpage of the package. Further, by electrically connecting the upper and lower RDL structures through the first and second conductive through hole vias, the present invention allows disposing of other packages or electronic elements.

The descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method of fabricating a semiconductor package, comprising:
providing a carrier having an adhesive layer formed on a surface thereof;
providing at least a chip having an active surface with a plurality of electrode pads and a non-active surface opposite to the active surface, and disposing the chip on the adhesive layer through the active surface thereof;
forming a soft layer on the adhesive layer for encapsulating the chip, wherein the soft layer has a first surface in contact with the adhesive layer and a second surface opposite to the first surface;
forming a support layer on the second surface of the soft layer so as to sandwich the soft layer between the support layer and the adhesive layer, wherein the support layer has a third surface opposite to the second surface of the soft layer;
removing the carrier and the adhesive layer so as to expose the active surface of the chip from the first surface of the soft layer;
forming a plurality of first conductive through hole vias in the soft layer;
forming a first redistribution layer (RDL) structure on the active surface of the chip and the first surface of the soft layer such that the first RDL structure is electrically connected to the first conductive through hole vias;
forming in the support layer a plurality of second conductive through hole vias in electrical connection with the first conductive through hole vias; and
forming a second RDL structure on the third surface of the support layer such that the second RDL structure is electrically connected to the first RDL structure through the first and second conductive through hole vias.

2. The method of claim 1, wherein forming the first RDL structure further comprises:
forming a first dielectric layer on the active surface of the chip and the first surface of the soft layer;
forming a first circuit layer on the first dielectric layer, and forming a plurality of first conductive vias in the first dielectric layer for electrically connecting the first circuit layer to the electrode pads of the chip and the first conductive through hole vias; and
forming a first insulating layer on the first dielectric layer and the first circuit layer, and exposing a portion of the first circuit layer from the first insulating layer.

3. The method of claim 2, further comprising forming a plurality of conductive elements on the exposed portion of the first circuit layer.

4. The method of claim 1, before forming the second conductive through hole vias in the support layer, further comprising thinning the support layer.

5. The method of claim 1, wherein forming the second RDL structure further comprises:
forming a second dielectric layer on the third surface of the support layer;
forming a second circuit layer on the second dielectric layer, and forming a plurality of second conductive vias in the second dielectric layer for electrically connecting the second circuit layer and the second conductive through hole vias; and
forming a second insulating layer on the second dielectric layer, and the second circuit layer and exposing a portion of the second circuit layer from the second insulating layer.

6. The method of claim 1, wherein forming the first conductive through hole vias further comprises:
forming a plurality of first through holes in the soft layer; and
forming the first conductive through hole vias in the first through holes.

7. The method of claim 1, wherein forming the second conductive through hole vias further comprises:
forming a plurality of second through holes in the support layer; and
forming the second conductive through hole vias in the second through holes.

8. A semiconductor package, comprising:
a soft layer having opposite first and second surfaces and a plurality of first conductive through hole vias;
at least a chip embedded in the soft layer, wherein the chip has an active surface with a plurality of electrode pads and a non-active surface opposite to the active surface, and the active surface of the chip is exposed from the first surface of the soft layer;
a support layer formed on the second surface of the soft layer and having a third surface opposite to the second surface of the soft layer, wherein a plurality of second conductive through hole vias are formed in the support layer and in electrical connection with the first conductive through hole vias;
a first RDL structure formed on the active surface of the chip and the first surface of the soft layer and electrically connected to the electrode pads of the chip and the first conductive through hole vias of the soft layer; and
a second RDL structure formed on the third surface of the support layer and electrically connected to the first RDL structure through the first and second conductive through hole vias.

9. The semiconductor package of claim 8, wherein the first RDL structure further comprises:
a first dielectric layer formed on the active surface of the chip and the first surface of the soft layer;
a first circuit layer formed on the first dielectric layer;
a plurality of first conductive vias formed in the first dielectric layer for electrically connecting the first circuit layer to the electrode pads of the chip and the first conductive through hole vias; and
a first insulating layer formed on the first dielectric layer and the first circuit layer and exposing a portion of the first circuit layer.

10. The semiconductor package of claim 9, further comprising a plurality of conductive elements disposed on the exposed portion of the first circuit layer.

11. The semiconductor package of claim 8, wherein the second RDL structure further comprises:
a second dielectric layer formed on the third surface of the support layer;
a second circuit layer formed on the second dielectric layer;
a plurality of second conductive vias formed in the second dielectric layer for electrically connecting the second circuit layer and the second conductive through hole vias; and
a second insulating layer formed on the second dielectric layer and the second circuit layer and exposing a portion of the second circuit layer.

12. The semiconductor package of claim 8, wherein the support layer is made of silicon, and the second conductive through hole vias are through silicon vias.

13. The semiconductor package of claim 8, wherein the support layer is made of glass, and the second conductive through hole vias are through glass vias.

14. The semiconductor package of claim 8, wherein the soft layer is made of ajinomoto build-up film, polyimide or silicone.
